(19) United States
(12) Patent Application Publication
(10) Pub. No.: US 2019/0025635 A1
(43) Pub. Date: Jan. 24, 2019

(54) DISPLAY PANEL AND DISPLAY DEVICE

(71) Applicants: HKC Corporation Limited, Shenzhen City (TW); Chongqing HKC Optoelectronics Technology Co., ltd., Chongqing (CN)

(72) Inventor: YU-JEN CHEN, Chongqing (CN)

(21) Appl. No.: 15/857,057

(22) Filed: Dec. 28, 2017

Related U.S. Application Data
(63) Continuation of application No. PCT/CN2017/099597, filed on Aug. 30, 2017.

(30) Foreign Application Priority Data
Jul. 21, 2017 (CN) 201710605229.1

(51) Int. Cl. G02F 1/1335; G02F 1/1368; G02F 1/1362; H01L 27/12

(52) U.S. Cl. CPC G02F 1/133512; G02F 1/1368; H01L 29/78633; H01L 27/124; H01L 27/1248; G02F 1/136286

(57) ABSTRACT

The present application discloses a panel pixel and a display device. The display panel, including a first substrate including a plurality of pixels thereof; and a second substrate disposed opposite to the first substrate; wherein the pixel includes pixel units having different colors, the pixel units with the same color are arranged immediately adjacent to each other to form a same color pixel unit group, the first substrate further includes a light shielding layer only surrounding the boundary of the same color pixel unit group with the same color.

### FIELD OF THE DISCLOSURE

The disclosure relates to a display technical field, and more particularly to a display panel and a display device.

### BACKGROUND

Liquid crystal display with a thin body, power saving, no radiation and many other advantages, has been widely used. Most of the liquid crystal displays in the market are backlight-type liquid crystal displays, including liquid crystal display panels and backlight modules. The working principles of the liquid crystal panel is placing liquid crystal molecules between two parallel glass substrates, and applying a driving voltage to the two glass substrates to control the rotation direction of the liquid crystal molecules to reflect the light emitted from the backlight module to produce an image.

Wherein, the active switch liquid crystal display (thin film transistor-liquid crystal display, TFT-LCD) has a low power consumption, excellent image quality and higher production yield and other performance, has gradually occupied the dominant position in the display area now. Similarly, the active switch liquid crystal display includes a liquid crystal panel and a backlight module, the liquid crystal panel includes a color filter substrate (CF substrate), an active switch array substrate (thin film transistor substrate, TFT substrate) and a mask, the related inner side of the substrates is provided a transparent electrode. Liquid crystals (LC) are sandwiched between the two substrates.

A shading is needed for arrangement in accordance with the design of the pixel structure to prevent leakage of light, wherein, a vertical shading is covering a data line and prevent for light leakage, a horizontal shading is covering a scanning line and prevent for light leakage, at the same time, the use of shading will affect the aperture ratio. However, with the demand of display panel resolution is getting higher and higher, the area of pixel is getting smaller and smaller, the lower the aperture ratio caused the brightness needed is provided by the increased of backlight plate, power consumption and not environmentally friendly.

### SUMMARY

The technical problem to be solved by the present application is to provide a display panel for increasing the aperture ratio.

In addition, the present application also provides a display device including the display panel described above.

The object of the present application is achieved by the following technology approach: a display panel, including:

a first substrate including a plurality of pixels thereof; and

a second substrate disposed opposite to the first substrate;

Wherein the pixel includes pixel units having different colors, the pixel units with the same color are arranged immediately adjacent to each other to form a same color pixel unit group, the first substrate further includes a light shielding layer, the light shielding layer only surrounds the boundary of the same color pixel unit group with the same color.

Wherein the pixel units with the same color in two adjacent pixels are arranged adjacent to each other, each of the pixel includes a first pixel unit, a second pixel unit, and a third pixel unit; the pixel units are sequentially arranged along a predetermined direction in the order of the first pixel unit, the second pixel unit, the third pixel unit, the third pixel unit, the first pixel unit and the second pixel unit; and the light shielding layer surrounds the boundaries of the pixel units, a plurality of light transmission regions is formed on the plurality of the pixels by the light shielding layer, each of the light transmission region includes a first light transmission region, a second light transmission region, and a third light transmission region, the first light transmission region is corresponding to one of the first pixel unit, the second light transmission region is corresponding to one of the second pixel unit, and the third light transmission region is corresponding to two of the third pixel units. Three pixel units is a group, two pixel units with the same color are arranged immediately, as an asymmetrical arrangement.

Wherein the pixel units with the same color in two adjacent pixels are arranged adjacent to each other, each of the pixel includes a first pixel unit, a second pixel unit, and a third pixel unit; the pixel units are sequentially arranged along a predetermined direction in the order of the first pixel unit, the second pixel unit, the third pixel unit, the third pixel unit, the second pixel unit and the first pixel unit; and the light shielding layer surrounds the boundaries of the pixel units, a plurality of light transmission regions is formed on the plurality of the pixels by the light shielding layer, each of the light transmission region includes a first light transmission region, a second light transmission region, and a third light transmission region, the first light transmission region is corresponding to two of the first pixel unit, the second light transmission region is corresponding to one of the second pixel unit, and the third light transmission region is corresponding to two of the third pixel units. Three pixel units is a group, two pixel units with the same color are arranged immediately, as a mirror symmetrical arrangement.

Wherein the second substrate includes a plurality of active switches and signal lines connected to the active switches, the active switches is corresponding to the each of the pixels; the signal lines includes a Nth signal line and a N−1th signal line arranged adjacent to each other in the same direction, the active switch corresponding to the Nth signal line is disposed opposite to the active switch corresponding to the N−1th signal line, the signal lines includes the Nth signal line and a N+1th signal line are arranged adjacent to each other in the same direction, the active switch corresponding to the Nth signal line is disposed facing to the active switch corresponding to the N+1th signal line; the distance between the Nth signal line and the N−1th signal line is smaller than the distance between the Nth signal line and the N+1th signal line; and the light shielding layer is disposed in a position corresponding to the Nth signal line and the N+1th signal line. The corresponding adjacent two signal lines are arranged adjacent to the shading material in the direction, thereby effectively reducing the coverage area of the light shielding layer on the first substrate and increasing the area of the light transmission area so that the aperture ratio is increased.

Wherein the signal lines include scanning lines coupled to a gate driver of the display panel; the light shielding layer is disposed on the scanning lines and its intersecting direction; and the first light transmission region is corresponding to four of the first pixel units, the second light transmission region is corresponding to two of the second pixel units, the third light transmission region is corresponding to four of the third pixel units. The scanning lines are commonly used signal lines in the display panel, arrangement and the maintenance is more convenient, reduce processing difficulty, save cost. The adjacent two scanning lines are arranged adjacent to the shading material in the direction, the light transmission region is remarkably improved by the change of the scanning line setting, the aperture ratio is increased, and the supply of the brightness of the backlight module is reduced and the cost is saved.

Wherein the signal lines include data lines coupled to a source driver of the display panel; the light shielding layer is disposed on the data lines and its intersecting direction, and the first light transmission region is corresponding to four of the first pixel units, the second light transmission region is corresponding to two of the second pixel units, the third light transmission region is corresponding to four of the third pixel units. The data lines are as a commonly used signal lines of the display panel, the arrangement and maintenance is more convenient, to reduce the difficulty of processing, cost savings. The adjacent two data lines are arranged close to the shading material in the direction, and the light transmission region is significantly improved, due to the change in the setting of the data lines, the aperture ratio is increased, and the supply of the brightness of the backlight module is reduced and the cost is saved.

Wherein the first pixel unit, the second pixel unit, and the third pixel unit are arranged sequentially along the direction of the signal line with the same direction. The pixel arrangement is adapting the RGB strip, for gate on array, GOA panel display panel design. It is also possible to use tri-gate pixel arrangement by the allowance with the charging time.

Wherein the first pixel unit is a red pixel unit, the second pixel unit is a green pixel unit, and the third pixel unit is a blue pixel unit;

Or the first pixel unit is the red pixel unit, the second pixel unit is the blue pixel unit, and the third pixel unit is the green pixel unit;

Or the first pixel unit is the green pixel unit, the second pixel unit is the blue pixel unit, and the third pixel unit is the red pixel unit;

Or the first pixel unit is the green pixel unit, the second pixel unit is the red pixel unit, and the third pixel unit is the blue pixel unit;

Or the first pixel unit is the blue pixel unit, the second pixel unit is the red pixel unit, and the third pixel unit is the green pixel unit;

Or the first pixel unit is the blue pixel unit, and the second pixel unit is the green pixel unit, and the third pixel unit is the red pixel unit. The pixel unit is adapting a red, green, and blue pixel unit. It is easy to satisfy the demand of the display panel by using the basic three primary color pixel unit, of course, it may further include a pixel unit corresponding to the colors such as White, W, Yellow, Y, the color is richer, the display performance is also better. According to another aspect of the present application, the present application also discloses a display panel, including:

A first substrate including a plurality of pixels thereof; a second substrate disposed opposite to the first substrate; wherein the pixel includes pixel units having different colors, the pixel units with the same color are arranged immediately adjacent to each other to form a same color pixel unit group, the first substrate further includes a light shielding layer, the light shielding layer only surrounds the boundary of the same color pixel unit group with the same color; wherein the pixel units with the same color in two adjacent pixels are arranged adjacent to each other, each of the pixel includes a first pixel unit, a second pixel unit, and a third pixel unit, the pixel units are sequentially arranged along a predetermined direction in the order of the first pixel unit, the second pixel unit, the third pixel unit, the third pixel unit, the first pixel unit and the second pixel unit, the light shielding layer surrounds the boundaries of the pixel units, a plurality of light transmission regions is formed on the plurality of the pixels by the light shielding layer, each of the light transmission region includes a first light transmission region, a second light transmission region, and a third light transmission region, the first light transmission region is corresponding to one of the first pixel unit, the second light transmission region is corresponding to one of the second pixel unit, and the third light transmission region is corresponding to two of the third pixel units; and wherein the second substrate includes a plurality of active switches and signal lines connected to the active switches, the active switches is corresponding to the each of the pixels; the signal lines includes a Nth signal line and a N−1th signal line arranged adjacent to each other in the same direction, the active switch corresponding to the Nth signal line is disposed opposite to the active switch corresponding to the N−1th signal line, the signal lines includes the Nth signal line and a N+1th signal line arranged adjacent to each other in the same direction, the active switch corresponding to the Nth signal line is disposed facing to the active switch corresponding to the N+1th signal line; the distance between the Nth signal line and the N−1th signal line is smaller than the distance between the Nth signal line and the N+1th signal line; the light shielding layer is disposed in a position corresponding to the Nth signal line and the N+1th signal line.

According to another aspect of the present application, the present application also discloses a display device including a control unit and a display panel as described above.

The present invention can effectively reduce the coverage area of the light shielding layer on the first substrate and increase the area of the light transmission region, so that the aperture ratio is increased, because the adjacent pixel units with the same color are disposed adjacent to the light shielding material surrounding them.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the FIG. s:

FIG. 1 is a schematic view of a first substrate structure of a display panel of an embodiment of the present application;

FIG. 2 is a schematic view of a first substrate structure of the display panel according to an embodiment of the present application;

FIG. 3 is a schematic view of a first substrate structure of the display panel according to an embodiment of the present application;

FIG. 4 is a schematic view of a first substrate structure of the display panel according to an embodiment of the present application;

FIG. 5 is a schematic view of a second substrate structure of a display panel according to an embodiment of the present invention;

FIG. 6 is a schematic view of the first substrate structure of a display panel of an embodiment of the present application;

FIG. 7 is a schematic view of the second substrate structure of a display panel according to an embodiment of the present application;

FIG. 8 is a schematic view of the first substrate structure of a display panel of an embodiment of the present application; and

FIG. 9 is a schematic view of a display device according to an embodiment of the present application.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

In the description of the disclosure, terms such as “center”, “transverse”, “above”, “below”, “left”, “right”, “vertical”, “horizontal”, “top”, “bottom”, “inside”, “outside”, etc. for indicating orientations or positional relationships refer to orientations or positional relationships as shown in the drawings; the terms are for the purpose of illustrating the disclosure and simplifying the description rather than indicating or implying the device or element must have a certain orientation and be structured or operated by the certain orientation, and therefore cannot be regarded as limitation with respect to the disclosure. Moreover, terms such as “first” and “second” are merely for the purpose of illustration and cannot be understood as indicating or implying the relative importance or implicitly indicating the number of the technical feature. Therefore, features defined by “first” and “second” can explicitly or implicitly include one or more the features. In the description of the disclosure, unless otherwise indicated, the meaning of “plural” is two or more than two. In addition, the term “comprise” and any variations thereof are meant to cover a non-exclusive inclusion.

In the description of the disclosure, is should be noted that, unless otherwise clearly stated and limited, terms “mounted”, “connected with” and “connected to” should be understood broadly, for instance, can be a fixed connection, a detachable connection or an integral connection; can be a mechanical connection, can also be an electrical connection; can be a direct connection, can also be an indirect connection by an intermediary, can be an internal communication of two elements. A person skilled in the art can understand concrete meanings of the terms in the disclosure as per specific circumstances.

The terms used herein are only for illustrating concrete embodiments rather than limiting the exemplary embodiments. Unless otherwise indicated in the content, singular forms “a” and “an” also include plural. Moreover, the terms “comprise” and/or “include” define the existence of described features, integers, steps, operations, units and/or components, but do not exclude the existence or addition of one or more other features, integers, steps, operations, units, components and/or combinations thereof.

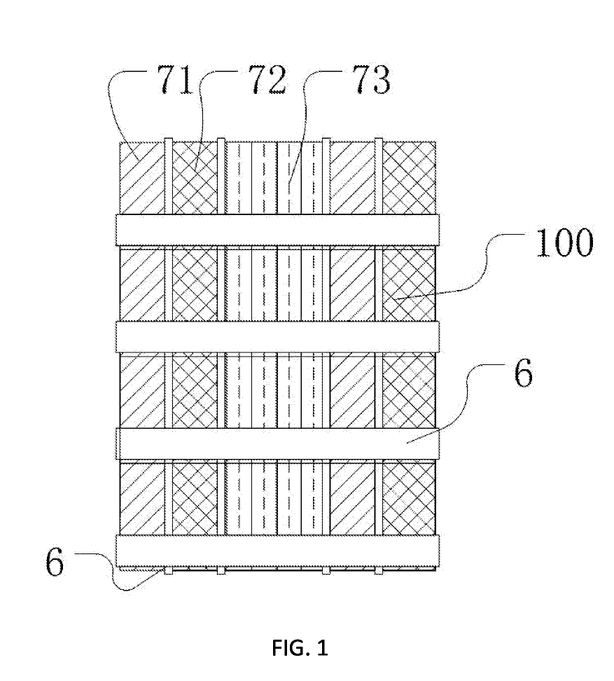

The display panel and the display device of the present application will be described in further detail below with reference to the embodiments of FIGS. 1 to 9.

As an embodiment of the present application, as shown in FIGS. 1-4, 6, and 8, a display panel includes a first substrate 100, a plurality of pixels are disposed on the first substrate 100, and a second substrate 200, the second substrate 200 is disposed opposite to the first substrate 100; wherein, the pixel includes pixel units having different colors, the pixel units with the same color are arranged immediately adjacent to each other to form a same color pixel unit group, the first substrate 100 further includes a light shielding layer only surrounding the boundary of the same color pixel unit group with the same color. The adjacent pixel units with the same color arranged immediately adjacent to each other are surrounded by the light shielding layer around the four boundaries. The coverage area of the light shielding layer on the first substrate 100 can be effectively reduced, and the area of the light transmission region is increased, so that the aperture ratio is increased.

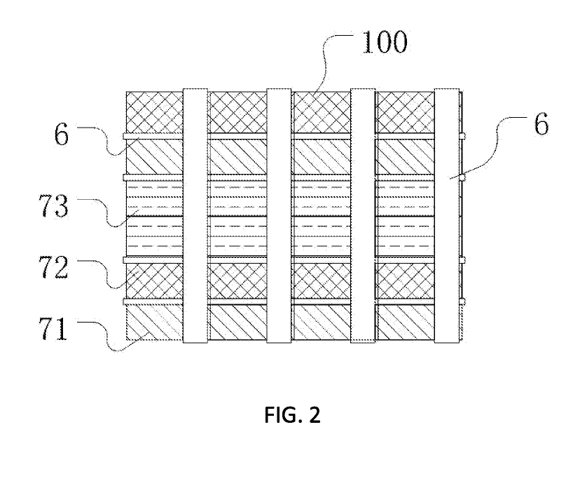

As an embodiment of the present application, as shown in FIGS. 1-2, the display panel includes the first substrate 100, the plurality of pixels are disposed on the first substrate 100, and the second substrate 200, the second substrate 200 is disposed opposite to the first substrate 100; wherein, the pixel includes pixel units having different colors, the pixel units with the same color are arranged immediately adjacent to each other to form a same color pixel unit group, the first substrate 100 further includes the light shielding layer only surrounding the boundary of the same color pixel unit group with the same color. The adjacent pixel units with the same color arranged immediately adjacent to each other are surrounded by the light shielding layer around the four boundaries. The coverage area of the light shielding layer on the first substrate 100 can be effectively reduced, and the area of the light transmission region is increased, so that the aperture ratio is increased. Wherein the pixel includes a first pixel unit, a second pixel unit, a third pixel unit, the pixel units are sequentially arranged along a predetermined direction of the order of the first pixel unit, the second pixel unit, the third pixel unit, the third pixel unit, the first pixel unit and the second pixel unit; the light shielding layer surrounds the pixel unit to form a plurality of light transmission regions, the light transmission region includes a first light transmission region, a second light transmission region, and a third light transmission region, the first light transmission region corresponding to one of the first pixel unit, the second light transmission region corresponding to one of the second pixel unit, and the third light transmission region corresponding to two of the third pixel units. Three pixel units are set as a group; the two pixel units with the same color are arranged immediately adjacent to each other to form an asymmetrical type arrangement.

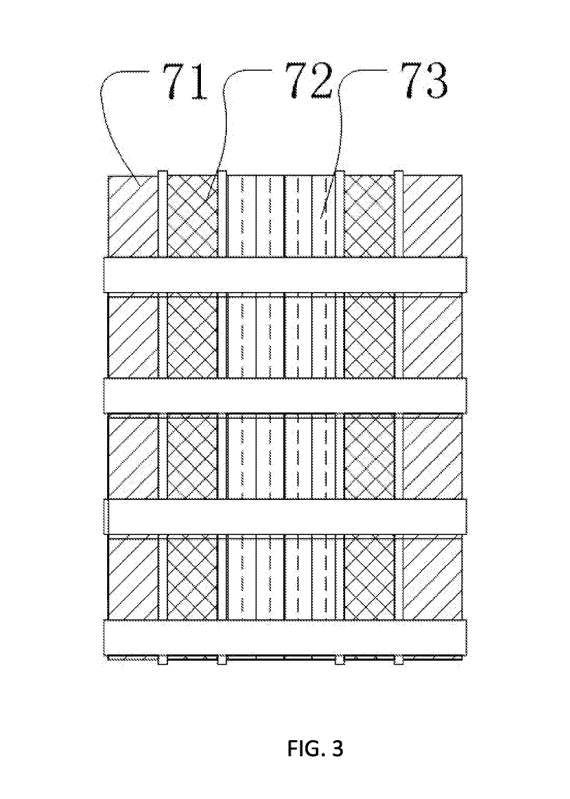

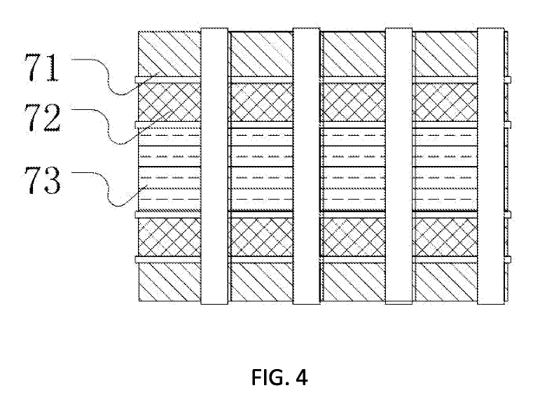

As an embodiment of the present application, as shown in FIGS. 3-4, the display panel includes the first substrate 100, the plurality of pixels are disposed on the first substrate 100, and the second substrate 200, the second substrate 200 is disposed opposite to the first substrate 100; wherein, the pixel includes pixel units having different colors, the pixel units with the same color are arranged immediately adjacent to each other to form a same color pixel unit group, the first substrate 100 further includes the light shielding layer only surrounding the boundary of the same color pixel unit group with the same color. The adjacent pixel units with the same color arranged immediately adjacent to each other are surrounded by the light shielding layer around the four boundaries. The coverage area of the light shielding layer on the first substrate 100 can be effectively reduced, and the area of the light transmission region is increased, so that the aperture ratio is increased. Wherein the pixel includes a first pixel unit, a second pixel unit, a third pixel unit, the pixel units are sequentially arranged along a predetermined direction of the order of the first pixel unit, the second pixel unit, the third pixel unit, the third pixel unit, the second pixel unit and the first pixel unit; the light shielding layer surrounds the pixel unit to form the plurality of light transmission regions, the light transmission region includes the first light transmission region, the second light transmission region, and the third light transmission region, the first light transmission region corresponding to two of the first pixel units, the second light transmission region corresponding to one of the second pixel unit, and the third light transmission region corresponding to two of the third pixel units. Three pixel units are set as a group; the two pixel units with the same color are arranged immediately adjacent to each other to form a mirror symmetrical arrangement.

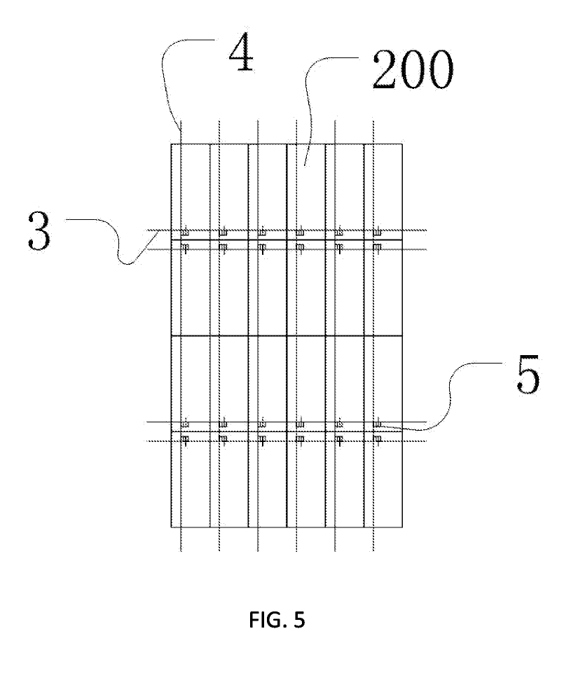

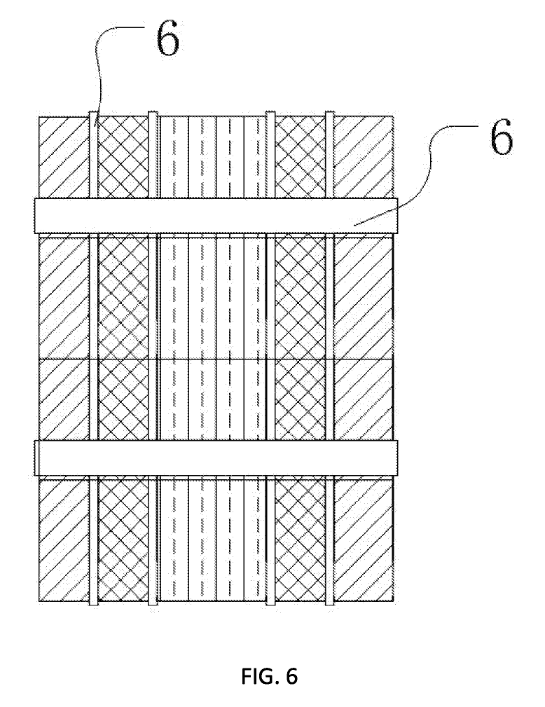

As an embodiment of the present application, as shown in FIGS. 5-6, the display panel includes the first substrate 100, the plurality of pixels are disposed on the first substrate 100, and the second substrate 200, the second substrate 200 is disposed opposite to the first substrate 100; wherein, the pixel includes pixel units having different colors, the pixel units with the same color are arranged immediately adjacent to each other to form a same color pixel unit group, the first substrate 100 further includes the light shielding layer only surrounding the boundary of the same color pixel unit group with the same color. The adjacent pixel units with the same color arranged immediately adjacent to each other are surrounded by the light shielding layer around the four boundaries. The coverage area of the light shielding layer on the first substrate 100 can be effectively reduced, and the area of the light transmission region is increased, so that the aperture ratio is increased. Wherein the pixel includes a first pixel unit, a second pixel unit, a third pixel unit, the pixel units are sequentially arranged along a predetermined direction of the order of the first pixel unit, the second pixel unit, the third pixel unit, the third pixel unit, the second pixel unit and the first pixel unit; the light shielding layer surrounds the pixel unit to form the plurality of light transmission regions, the light transmission region includes the first light transmission region, the second light transmission region, and the third light transmission region, the first light transmission region corresponding to two of the first pixel units, the second light transmission region corresponding to one of the second pixel unit, and the third light transmission region corresponding to two of the third pixel units. The second substrate 200 is provided with a plurality of active switches 5 corresponding to the each of the pixels and signal lines connected to the active switches 5; an active switch 5 corresponding to a Nth signal line is disposed opposite to an active switch 5 corresponding to a N−1th signal line in the same direction and adjacent to each other. The active switch 5 corresponding to the Nth signal line is disposed facing to an active switch 5 corresponding to a N+1th signal line; the distance between the Nth signal line and the N−1th signal line is smaller than the distance between the Nth signal line and the N+1th signal line; the light shielding layer is disposed in the position corresponding to the Nth signal line and the N+1th signal line. The corresponding two signal lines are arranged immediately adjacent to each other and share the light shielding layer in the direction to effectively reduce the coverage area of the light shielding layer on the first substrate 100 and to increase the area of the light transmission region, so that the aperture ratio is increased. The signal lines includes a first signal line and a second signal line, the signal lines are intersecting arranged subsequently, the first signal line and the second signal line are matched with the contour curve of the pixel, to ensure whether the shape of the pixel, the pixel electrode can work properly. The aperture ratio is further increased, by using the properties of the adjacent two signal lines arranged immediately adjacent to each other to share the light shielding layer in the direction, and the adjacent pixel units with the same color arranged immediately adjacent to each other to share the light shielding layer surrounding the boundary of the pixel unit in the same time.

The signal lines includes a scanning line 3 coupled to the gate driver of the display panel, the light shielding layer is disposed in the scanning line 3 and its intersecting direction, the first light transmission region corresponds to four of the first pixel units, the second light transmission region corresponds to two of the second pixel units, the third light transmission region corresponds to four of the third pixel units. The scanning lines 3 are as common signal lines of the display panel, the arrangement and maintenance of the use are more convenient, to reduce the difficulty of processing, cost savings. The adjacent two scanning lines 3 are arranged immediately adjacent to each other to share the light shielding layer in the direction, the light transmission region is remarkably improved by the change in the setting of the scanning line 3, the aperture ratio is increased, and demand of the supply of the luminance of the backlight module is reduced, and the cost is saved. On the second substrate 200, the adjacent active switch 5 corresponding to the Nth scanning line 3 along the vertical signal lines direction (may be the data line 4) and the active switch 5 corresponding to the N−1th scanning line 3 are opposite disposed, the active switch 5 corresponding to the Nth scanning line 3 is disposed facing to the active switch 5 corresponding to the N+1th scanning line 3; the distance between the Nth scanning line 3 and the N−1th scanning line 3 is smaller than the distance between the Nth scanning line 3 and the N+1th scanning line 3; the corresponding two adjacent scanning lines 3 are arranged immediately adjacent to each other. On the first substrate 100, using pixel arrangement of RGB strip, the black matrix 6 covers the corresponding positions of the scanning lines 3 and the signal lines in the color filter layer, in this time, the two immediately adjacent scanning lines 3 share the light shielding layer in the horizontal direction, the coverage area of the light shielding layer on the second substrate 200 can be effectively reduced, and the area of the light transmission region is increased, so that the aperture ratio is increased. Wherein the area of the light transmission region is about twice the area of the light transmission region when the active switches 5 are uniformly disposed in the direction of the scanning line 3 and are uniformly disposed in the direction of the data line 4 at the same time.

Wherein the first pixel unit, the second pixel unit, and the third pixel unit are sequentially arranged in the same direction of the signal line direction. By using pixel arrangement of RGB strip, it is suitable for the display panel design of gate on array, GOA panel. The first pixel unit is a red pixel unit 71, the second pixel unit is a green pixel unit 72, the third pixel unit is a blue pixel unit 73; or the first pixel unit is a red pixel unit 71, the second pixel unit is a blue pixel unit 73, the third pixel unit is a green pixel unit 72; or the first pixel unit is a green pixel unit 72, and the second pixel unit is a blue pixel unit 73, the third pixel unit is a red pixel unit 71; or, the first pixel unit is a green pixel unit 72, the second pixel unit is a red pixel unit 71, the third pixel unit is a blue pixel unit 73; or the first pixel unit is a blue pixel unit 73, the second pixel unit is a red pixel unit 71, the third pixel unit is a green pixel unit 72; or the first pixel unit is a blue pixel unit 73, and the second pixel unit is a green pixel unit 72, the third pixel unit is a red pixel unit 71. The pixel unit is adapting a red, green, and blue pixel unit 73. It is easy to satisfy the demand of the display panel by using the basic three primary color pixel unit, of course, it may further include a pixel unit corresponding to the colors such as White, W, Yellow, Y, the color is richer, the display performance is also better. Wherein, the pixel unit is rectangular structure.

Wherein the light shielding layer uses a black matrix, BM 6. The black matrix 6 is a commonly used light shielding layer, regardless of the process or use are more convenient. The active switches 5 may employ thin film transistors.

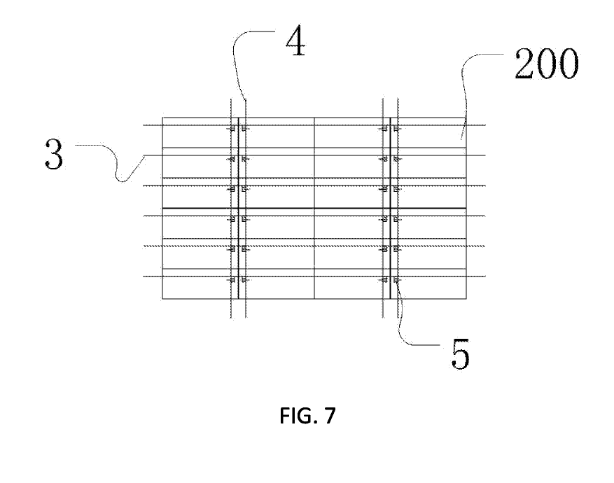

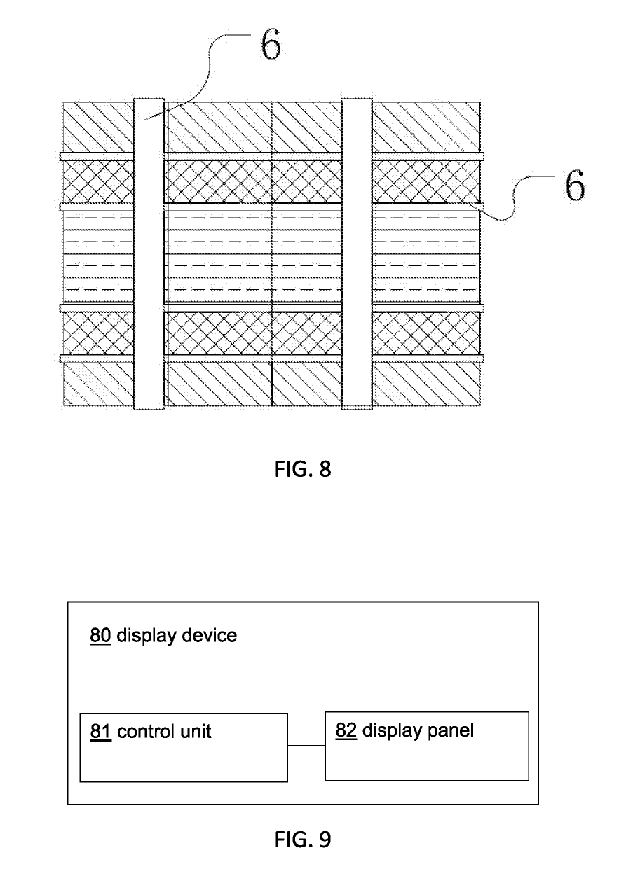

As an embodiment of the present application, as shown in FIGS. 7-8, the display panel includes the first substrate 100, the plurality of pixels are disposed on the first substrate 100, and the second substrate 200, the second substrate 200 is disposed opposite to the first substrate 100; wherein, the pixel includes pixel units having different colors, the pixel units with the same color are arranged immediately adjacent to each other to form a same color pixel unit group, the first substrate 100 further includes the light shielding layer only surrounding the boundary of the same color pixel unit group with the same color. The adjacent pixel units with the same color arranged immediately adjacent to each other are surrounded by the light shielding layer around the four boundaries. The coverage area of the light shielding layer on the first substrate 100 can be effectively reduced, and the area of the light transmission region is increased, so that the aperture ratio is increased. Wherein the pixel includes a first pixel unit, a second pixel unit, a third pixel unit, the pixel units are sequentially arranged along a predetermined direction of the order of the first pixel unit, the second pixel unit, the third pixel unit, the third pixel unit, the second pixel unit and the first pixel unit; the light shielding layer surrounds the pixel unit to form the plurality of light transmission regions, the light transmission region includes the first light transmission region, the second light transmission region, and the third light transmission region, the first light transmission region corresponding to two of the first pixel units, the second light transmission region corresponding to one of the second pixel unit, and the third light transmission region corresponding to two of the third pixel units. The second substrate 200 is provided with a plurality of active switches 5 corresponding to the each of the pixels and signal lines connected to the active switches 5; an active switch 5 corresponding to a Nth signal line is disposed opposite to an active switch 5 corresponding to a N−1th signal line in the same direction and adjacent to each other. The active switch 5 corresponding to the Nth signal line is disposed facing to an active switch 5 corresponding to a N+1th signal line; the distance between the Nth signal line and the N−1th signal line is smaller than the distance between the Nth signal line and the N+1th signal line; the light shielding layer is disposed in the position corresponding to the Nth signal line and the N+1th signal line. The corresponding two signal lines are arranged immediately adjacent to each other and share the light shielding layer in the direction to effectively reduce the coverage area of the light shielding layer on the first substrate 100 and to increase the area of the light transmission region, so that the aperture ratio is increased. The signal lines includes a first signal line and a second signal line, the signal lines are intersecting arranged subsequently, the first signal line and the second signal line are matched with the contour curve of the pixel, to ensure whether the shape of the pixel, the pixel electrode can work properly. The aperture ratio is further increased, by using the properties of the adjacent two signal lines arranged immediately adjacent to each other to share the light shielding layer in the direction, and the adjacent pixel units with the same color arranged immediately adjacent to each other to share the light shielding layer surrounding the boundary of the pixel unit in the same time.

The signal lines includes a data line 4 coupled to the source driver of the display panel, the light shielding layer is disposed in the data line 3 and its intersecting direction, the first light transmission region corresponds to four of the first pixel units, the second light transmission region corresponds to two of the second pixel units, the third light transmission region corresponds to four of the third pixel units. The data line lines 3 are as common signal lines of the display panel, the arrangement and maintenance of the use are more convenient, to reduce the difficulty of processing, cost savings. The adjacent two data lines 4 are arranged immediately adjacent to each other to share the light shielding layer in the direction, the light transmission region is remarkably improved by the change in the setting of the data lines 4, the aperture ratio is increased, and demand of the supply of the luminance of the backlight module is reduced, and the cost is saved. On the second substrate 200, the adjacent active switch 5 corresponding to the Nth data line 4 along the horizontal signal lines direction (may be the scanning line 3) and the active switch 5 corresponding to the N−1th data line 4 are opposite disposed, the active switch 5 corresponding to the Nth data line 4 is disposed facing to the active switch 5 corresponding to the N+1th data line 4; the distance between the Nth data line 4 and the N−1th data line 4 is smaller than the distance between the Nth data line 4 and the N+1th data line 4; the corresponding two adjacent data lines 4 are arranged immediately adjacent to each other. On the first substrate 100, using pixel arrangement of tri-gate, the black matrix 6 covers the corresponding positions of the signal lines and the data lines 4 in the color filter layer, in this time, the two immediately adjacent scanning lines 3 share the light shielding layer in the vertical direction, the coverage area of the light shielding layer on the first substrate 100 can be effectively reduced, and the area of the light transmission region is increased, so that the aperture ratio is increased. Wherein the area of the light transmission region is about twice the area of the light transmission region when the active switches 5 are uniformly disposed in the direction of the scanning line 3 and are uniformly disposed in the direction of the data line 4 at the same time.

Wherein the first pixel unit, the second pixel unit, and the third pixel unit are sequentially arranged in the same direction of the signal line direction. By using pixel arrangement of tri-gate. The first pixel unit is the red pixel unit 71, the second pixel unit is the green pixel unit 72, the third pixel unit is the blue pixel unit 73; or the first pixel unit is the red pixel unit 71, the second pixel unit is the blue pixel unit 73, the third pixel unit is the green pixel unit 72; or the first pixel unit is the green pixel unit 72, and the second pixel unit is the blue pixel unit 73, the third pixel unit is the red pixel unit 71; or, the first pixel unit is the green pixel unit 72, the second pixel unit is the red pixel unit 71, the third pixel unit is the blue pixel unit 73; or the first pixel unit is blue the pixel unit 73, the second pixel unit is the red pixel unit 71, the third pixel unit is the green pixel unit 72; or the first pixel unit is the blue pixel unit 73, and the second pixel unit is the green pixel unit 72, the third pixel unit is the red pixel unit 71. The pixel units are adapting the red, green, and blue pixel units 73. It is easy to satisfy the demand of the display panel by using the basic three primary color pixel unit, of course, it may further include a pixel unit corresponding to the colors such as White, W, Yellow, Y, the color is richer, the display performance is also better. Wherein, the pixel unit is rectangular structure.

Wherein the light shielding layer uses a black matrix, BM 6. The black matrix 6 is a commonly used light shielding layer, regardless of the process or use are more convenient. The active switches 5 may employ thin film transistors.

In the above embodiment, the display panel includes a liquid crystal panel, an Organic Light-Emitting Diode, OLED panel, a Quantum Dot Light Emitting Diodes, QLED panel, a plasma panel, a planar panel, a curved panel, and the like.

Referring to FIG. 9, the present embodiment discloses a display device 80. The display device 80 includes a control unit 81 and a display panel 82 described in the present application. The above description of the display panel structure is also applicable to the display device of the embodiment of the present application. Wherein when the display device of the embodiment of the present application is a liquid crystal display, the liquid crystal display includes a backlight module, the backlight module can be used as a light source for supplying a light source with sufficient brightness and uniform distribution, and the backlight module of the present embodiment can be a front light type, or it can be a back light type. It should be noted that the backlight module of the present embodiment is not limited thereto.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A display panel, comprising:
a first substrate comprising a plurality of pixels thereof; and
a second substrate disposed opposite to the first substrate;
wherein the pixel comprises pixel units having different colors, the pixel units with the same color are arranged immediately adjacent to each other to form a same color pixel unit group, the first substrate further comprises a light shielding layer, the light shielding layer only surrounds the boundary of the same color pixel unit group with the same color.

2. The display panel according to claim 1, wherein the pixel units with the same color in two adjacent pixels are arranged adjacent to each other, each of the pixel comprises a first pixel unit, a second pixel unit, and a third pixel unit;
the pixel units are sequentially arranged along a predetermined direction in the order of the first pixel unit, the second pixel unit, the third pixel unit, the third pixel unit, the first pixel unit and the second pixel unit; and
the light shielding layer surrounds the boundaries of the pixel units, a plurality of light transmission regions is formed on the plurality of the pixels by the light shielding layer, each of the light transmission region comprises a first light transmission region, a second light transmission region, and a third light transmission region, the first light transmission region is corresponding to one of the first pixel unit, the second light transmission region is corresponding to one of the second pixel unit, and the third light transmission region is corresponding to two of the third pixel units.

3. The display panel according to claim 1, wherein the pixel units with the same color in two adjacent pixels are arranged adjacent to each other, each of the pixel comprises a first pixel unit, a second pixel unit, and a third pixel unit;
the pixel units are sequentially arranged along a predetermined direction in the order of the first pixel unit, the second pixel unit, the third pixel unit, the third pixel unit, the second pixel unit and the first pixel unit; and
the light shielding layer surrounds the boundaries of the pixel units, a plurality of light transmission regions is formed on the plurality of the pixels by the light shielding layer, each of the light transmission region comprises a first light transmission region, a second light transmission region, and a third light transmission region, the first light transmission region is corresponding to two of the first pixel unit, the second light transmission region is corresponding to one of the second pixel unit, and the third light transmission region is corresponding to two of the third pixel units.

4. The display panel according to claim 2, wherein the second substrate comprises a plurality of active switches and signal lines connected to the active switches, the active switches is corresponding to the each of the pixels;
the signal lines comprises a Nth signal line and a N−1th signal line arranged adjacent to each other in the same direction, the active switch corresponding to the Nth signal line is disposed opposite to the active switch corresponding to the N−1th signal line, the signal lines comprises the Nth signal line and a N+1th signal line are arranged adjacent to each other in the same direction, the active switch corresponding to the Nth signal line is disposed facing to the active switch corresponding to the N+1th signal line; the distance between the Nth signal line and the N−1th signal line is smaller than the distance between the Nth signal line and the N+1th signal line; and
the light shielding layer is disposed in a position corresponding to the Nth signal line and the N+1th signal line.

5. The display panel according to claim 4, wherein the signal lines comprise scanning lines coupled to a gate driver of the display panel;
the light shielding layer is disposed on the scanning lines and its intersecting direction; and
the first light transmission region is corresponding to four of the first pixel units, the second light transmission region is corresponding to two of the second pixel units, the third light transmission region is corresponding to four of the third pixel units.

6. The display panel according to claim 4, wherein the signal lines comprise data lines coupled to a source driver of the display panel;
the light shielding layer is disposed on the data lines and its intersecting direction, and
the first light transmission region is corresponding to four of the first pixel units, the second light transmission region is corresponding to two of the second pixel units, the third light transmission region is corresponding to four of the third pixel units.

7. The display panel according to claim 4, wherein the first pixel unit, the second pixel unit, and the third pixel unit are arranged sequentially along the direction of the signal line with the same direction.

8. The display panel according to claim 5, wherein the first pixel unit, the second pixel unit, and the third pixel unit are arranged sequentially along the direction of the signal line with the same direction.

9. The display panel according to claim 6, wherein the first pixel unit, the second pixel unit, and the third pixel unit are arranged sequentially along the direction of the signal line with the same direction.

10. The display panel according to claim 2, wherein the first pixel unit is a red pixel unit, the second pixel unit is a green pixel unit, and the third pixel unit is a blue pixel unit;
or the first pixel unit is the red pixel unit, the second pixel unit is the blue pixel unit, and the third pixel unit is the green pixel unit;
or the first pixel unit is the green pixel unit, the second pixel unit is the blue pixel unit, and the third pixel unit is the red pixel unit;
or the first pixel unit is the green pixel unit, the second pixel unit is the red pixel unit, and the third pixel unit is the blue pixel unit;
or the first pixel unit is the blue pixel unit, the second pixel unit is the red pixel unit, and the third pixel unit is the green pixel unit;
or the first pixel unit is the blue pixel unit, and the second pixel unit is the green pixel unit, and the third pixel unit is the red pixel unit.

11. The display panel according to claim 3, wherein the first pixel unit is a red pixel unit, the second pixel unit is a green pixel unit, and the third pixel unit is a blue pixel unit;
or the first pixel unit is the red pixel unit, the second pixel unit is the blue pixel unit, and the third pixel unit is the green pixel unit;
or the first pixel unit is the green pixel unit, the second pixel unit is the blue pixel unit, and the third pixel unit is the red pixel unit;
or the first pixel unit is the green pixel unit, the second pixel unit is the red pixel unit, and the third pixel unit is the blue pixel unit;
or the first pixel unit is the blue pixel unit, the second pixel unit is the red pixel unit, and the third pixel unit is the green pixel unit;
or the first pixel unit is the blue pixel unit, and the second pixel unit is the green pixel unit, and the third pixel unit is the red pixel unit.

12. The display panel according to claim 4, wherein the first pixel unit is a red pixel unit, the second pixel unit is a green pixel unit, and the third pixel unit is a blue pixel unit;
or the first pixel unit is the red pixel unit, the second pixel unit is the blue pixel unit, and the third pixel unit is the green pixel unit;
or the first pixel unit is the green pixel unit, the second pixel unit is the blue pixel unit, and the third pixel unit is the red pixel unit;
or the first pixel unit is the green pixel unit, the second pixel unit is the red pixel unit, and the third pixel unit is the blue pixel unit;
or the first pixel unit is the blue pixel unit, the second pixel unit is the red pixel unit, and the third pixel unit is the green pixel unit;
or the first pixel unit is the blue pixel unit, and the second pixel unit is the green pixel unit, and the third pixel unit is the red pixel unit.

13. The display panel according to claim 5, wherein the first pixel unit is a red pixel unit, the second pixel unit is a green pixel unit, and the third pixel unit is a blue pixel unit;
or the first pixel unit is the red pixel unit, the second pixel unit is the blue pixel unit, and the third pixel unit is the green pixel unit;
or the first pixel unit is the green pixel unit, the second pixel unit is the blue pixel unit, and the third pixel unit is the red pixel unit;
or the first pixel unit is the green pixel unit, the second pixel unit is the red pixel unit, and the third pixel unit is the blue pixel unit;
or the first pixel unit is the blue pixel unit, the second pixel unit is the red pixel unit, and the third pixel unit is the green pixel unit;
or the first pixel unit is the blue pixel unit, and the second pixel unit is the green pixel unit, and the third pixel unit is the red pixel unit.

14. The display panel according to claim 6, wherein the first pixel unit is a red pixel unit, the second pixel unit is a green pixel unit, and the third pixel unit is a blue pixel unit;
or the first pixel unit is the red pixel unit, the second pixel unit is the blue pixel unit, and the third pixel unit is the green pixel unit;
or the first pixel unit is the green pixel unit, the second pixel unit is the blue pixel unit, and the third pixel unit is the red pixel unit;
or the first pixel unit is the green pixel unit, the second pixel unit is the red pixel unit, and the third pixel unit is the blue pixel unit;
or the first pixel unit is the blue pixel unit, the second pixel unit is the red pixel unit, and the third pixel unit is the green pixel unit;
or the first pixel unit is the blue pixel unit, and the second pixel unit is the green pixel unit, and the third pixel unit is the red pixel unit.

15. A display panel, comprising:
a first substrate comprising a plurality of pixels thereof;
a second substrate disposed opposite to the first substrate;
wherein the pixel comprises pixel units having different colors, the pixel units with the same color are arranged immediately adjacent to each other to form a same color pixel unit group, the first substrate further comprises a light shielding layer, the light shielding layer only surrounds the boundary of the same color pixel unit group with the same color;
wherein the pixel units with the same color in two adjacent pixels are arranged adjacent to each other, each of the pixel comprises a first pixel unit, a second pixel unit, and a third pixel unit, the pixel units are sequentially arranged along a predetermined direction in the order of the first pixel unit, the second pixel unit, the third pixel unit, the third pixel unit, the first pixel unit and the second pixel unit, the light shielding layer surrounds the boundaries of the pixel units, a plurality of light transmission regions is formed on the plurality of the pixels by the light shielding layer, each of the light transmission region comprises a first light transmission region, a second light transmission region, and a third light transmission region, the first light transmission region is corresponding to one of the first pixel unit, the second light transmission region is corresponding to one of the second pixel unit, and the third light transmission region is corresponding to two of the third pixel units; and
wherein the second substrate comprises a plurality of active switches and signal lines connected to the active switches, the active switches is corresponding to the each of the pixels; the signal lines comprises a Nth signal line and a N−1th signal line arranged adjacent to each other in the same direction, the active switch corresponding to the Nth signal line is disposed opposite to the active switch corresponding to the N−1th signal line, the signal lines comprises the Nth signal line and a N+1th signal line arranged adjacent to each other in the same direction, the active switch corresponding to the Nth signal line is disposed facing to the active switch corresponding to the N+1th signal line; the distance between the Nth signal line and the N−1th signal line is smaller than the distance between the Nth signal line and the N+1th signal line; the light shielding layer is disposed in a position corresponding to the Nth signal line and the N+1th signal line.

16. A display device, comprising:
a control unit; and
a display panel, comprising:
a first substrate comprising a plurality of pixels thereof; and
a second substrate disposed opposite to the first substrate;
wherein the pixel comprises pixel units having different colors, the pixel units with the same color are arranged immediately adjacent to each other to form a same color pixel unit group, the first substrate further comprises a light shielding layer, the light shielding layer only surrounds the boundary of the same color pixel unit group with the same color.

17. The display device according to claim 16, wherein the pixel units with the same color in two adjacent pixels are arranged adjacent to each other, each of the pixel comprises a first pixel unit, a second pixel unit, and a third pixel unit;
the pixel units are sequentially arranged along a predetermined direction in the order of the first pixel unit, the second pixel unit, the third pixel unit, the third pixel unit, the first pixel unit and the second pixel unit; and
the light shielding layer surrounds the boundaries of the pixel units, a plurality of light transmission regions is formed on the plurality of the pixels by the light shielding layer, each of the light transmission region comprises a first light transmission region, a second light transmission region, and a third light transmission region, the first light transmission region is corresponding to one of the first pixel unit, the second light transmission region is corresponding to one of the second pixel unit, and the third light transmission region is corresponding to two of the third pixel units.

18. The display panel according to claim 16, wherein the pixel units with the same color in two adjacent pixels are arranged adjacent to each other, each of the pixel comprises a first pixel unit, a second pixel unit, and a third pixel unit;
the pixel units are sequentially arranged along a predetermined direction in the order of the first pixel unit, the second pixel unit, the third pixel unit, the third pixel unit, the second pixel unit and the first pixel unit; and
the light shielding layer surrounds the boundaries of the pixel units, a plurality of light transmission regions is formed in the plurality of the pixels by the light shielding layer, each of the light transmission region comprises a first light transmission region, a second light transmission region, and a third light transmission region, the first light transmission region is corresponding to two of the first pixel unit, the second light transmission region is corresponding to one of the second pixel unit, and the third light transmission region is corresponding to two of the third pixel units.

19. The display device according to claim 17, wherein the second substrate comprises a plurality of active switches and signal lines connected to the active switches, the active switches is corresponding to the each of the pixels;
the signal lines comprises a Nth signal line and a N−1th signal line arranged adjacent to each other in the same direction, the active switch corresponding to the Nth signal line is disposed opposite to the active switch corresponding to the N−1th signal line, the signal lines comprises the Nth signal line and a N+1th signal line arranged adjacent to each other in the same direction, the active switch corresponding to the Nth signal line is disposed facing to the active switch corresponding to the N+1th signal line; the distance between the Nth signal line and the N−1th signal line is smaller than the distance between the Nth signal line and the N+1th signal line; and
the light shielding layer is disposed in a position corresponding to the Nth signal line and the N+1th signal line.

20. The display device according to claim 19, wherein the signal lines comprise scanning lines coupled to a gate driver of the display panel;
the light shielding layer is disposed on the scanning lines and its intersecting direction; and
the first light transmission region is corresponding to four of the first pixel units, the second light transmission region is corresponding to two of the second pixel units, the third light transmission region is corresponding to four of the third pixel units.
